(19) United States
(12) Patent Application Publication
(10) Pub. No.: US 2025/0385155 A1
(43) Pub. Date: Dec. 18, 2025

(54) PACKAGE STRUCTURE AND METHOD OF FORMING THE SAME

(71) Applicant: SUREWAY TECHNOLOGY CO.,LTD., Taichung City (TW)

(72) Inventors: Hsing-Hua TSAI, Taichung City (TW); Song-Huan SUN, Taichung City (TW); Ming-Chih HSU, Taichung City (TW); Tung-Han CHUANG, Taichung City (TW); Chih-Hsin TSAI, Taichung City (TW)

(73) Assignee: SUREWAY TECHNOLOGY CO.,LTD., Taichung City (TW)

(21) Appl. No.: 18/949,083

(22) Filed: Nov. 15, 2024

(30) Foreign Application Priority Data
Jun. 13, 2024 (TW) 113121781

(51) Int. Cl. H01L 23/367; H01L 23/373

(52) U.S. Cl. CPC H01L 23/3677; H01L 23/3735

(57) ABSTRACT

A package structure includes a substrate; a chip disposed on the substrate and having a backside surface away from the substrate; a fin heat sink having a surface facing the chip disposed above the substrate; a thermal interface material disposed between the chip and the fin heat sink; and a twinned layer disposed on at least one side of the thermal interface material and in direct contact with the thermal interface material. A method for forming the package structure is also provided.

### CROSS REFERENCE TO RELATED APPLICATIONS

This Application claims priority of Taiwan Patent Application No. 113121781, filed on Jun. 13, 2024, the entirety of which is incorporated by reference herein.

### BACKGROUND

### Field of the Invention

The disclosure relates to a package technology, and, in particular, to package structures with twinned layers and a method of forming the same.

### Description of the Related Art

Electronic components are developing in the direction of being light, thin, short, small, high performance, high transmission and high efficiency, and the heat quantity generated per unit area is also getting higher and higher. For example, in the past, a central processing unit (CPU) element using a Pentium processor had a heating value of only 20 W, but a Pentium 4 exceeded 80 W, and the temperature of the CPU during operation might reach over 150° C. According to a prediction of the future development process of the semiconductor industry proposed by the U.S. International Technology Roadmap for Semiconductors (ITRS). In the next few years, the heat output of low-level computers will increase from the current approximately 100 W to nearly 120 W, and the heat output of high-level computers will increase significantly from the original 150 W to more than 180 W. Working frequency will also increase from 2 GHz to 4 GHz or more.

To solve the problem of low heat dissipation power in traditional components, the simplest solution is to add fin heat sinks or cooling fans to improve the heat dissipation performance. However, as the functionality and thermal power density of electronic components significantly increase, the requirements for thermal management technology become more stringent. In the path through which heat from the component is transferred to the external environment, in addition to having a low thermal impedance in the chip itself and using high-performance heat dissipation components, both the bonding density between components and the thermal conductivity of the bonding materials are critical factors in determining whether the heat dissipation technology can achieve breakthroughs. In general, mechanical contact interfaces are often rough or even wavy, with numerous insulating gaps at the bonding site between two materials. These gaps may cause significant thermal conductivity barriers. Thermal interface material (TIM) is a material commonly used in integrated circuit (IC) package and electronic component heat dissipation. The main function of TIM is to fill the contact gaps between two materials, increase the heat dissipation performance of the system, and effectively reduce the thermal impedance. A good TIM should possess the following characteristics: (1) good heat dissipation properties, that is, high heat conductivity and low thermal impedance value; (2) ease of assembly and rework; (3) higher compressibility to withstand external compressive stress when being affixed to the bonding surface, and to properly fill the gaps between interfaces to facilitate heat flow propagation; (4) good wettability with electronic components and heat sinks; and (5) high reliability and long service life.

Thermal grease is one of the earliest types of TIMs, consisting of silicone or hydrocarbon compounds with various added fillers. The thermal impedance of traditional thermal grease is approximately 1 K·cm²/W and has been reduced to about 0.2 K·cm²/W in recent years. However, existing thermal grease still present many issues. For example, due to its high viscosity, it cannot completely fill the gaps at the bonding interfaces, and approximately 300 kPa of pressure must be applied to achieve optimal heat dissipation performance. In addition, due to the use of polymer materials, it may experience a pump-out effect because the material cannot withstand the relative displacement between the heat sink and the chip. Moreover, if thermal grease is exposed to high temperatures for a long time, the polymer materials may undergo chemical reactions and separate from the internal fillers, significantly reducing the wettability of the bonding interface. The aforementioned phenomenon is known as dry-out.

Elastomeric thermal pads are TIMs made from polymerized silicone rubber, used as a replacement for thermal grease. The thermal impedance of elastomeric thermal pads ranges from 1 K·cm²/W to 3 K·cm²/W, making them unsuitable for higher-level heat dissipation systems. It has the advantage of being easy to mold and assemble, but it requires the application of approximately 700 kPa of additional high pressure to function properly. Another type of TIM, thermal tapes, features an adhesive coated on substrates such as polyimide (PI), fiberglass, or aluminum foil. Thermal tapes have the advantage of not requiring additional mechanical clamping; however, their heat dissipation performance is still not satisfactory.

Phase change materials combine the excellent thermal conductivity of thermal grease with the ease of processing of elastomeric thermal pads, providing good thermal conductivity both above and below its melting point (approximately 50° C. to 80° C.). However, when the temperature exceeds the melting point, its adhesion decreases, so additional mechanical pressure (approximately 300 kPa) must still be applied during use. Although phase change materials offer excellent thermal impedance values comparable to those of thermal grease (approximately 0.3 K·cm²/W to 0.7 K·cm²/W) and may effectively address pump-out and dry-out issues, thermal grease is generally preferred for high-level heat dissipation systems due to considerations of reworkability.

To address the series of issues associated with polymer materials, the industry has developed low-melting-point alloy TIMs (with melting points ranging from approximately 40 to 200° C.). The main advantage is the use of the low melting point characteristics of certain eutectic indium-based alloys. The heat generated during the operation of the electronic components may melt the low-melting-point alloy into a liquid state, allowing it to fill the gaps at the bonding site. Particularly, the excellent thermal conductivity of the metal itself ensures effective heat dissipation.

However, the presence of voids in the TIMs may reduce the heat dissipation performance, thereby affecting the reliability of the package structure. While the existing package technology has generally been adequate for its intended purposes, it is not entirely satisfactory in all aspects.

### SUMMARY

One aspect of the disclosure pertains to a package structure. The package structure includes a substrate; a chip disposed on the substrate and having a backside surface away from the substrate; a heat sink disposed over the substrate, wherein the heat sink has a surface facing the chip; a thermal interface material (TIM) disposed between the chip and the heat sink; and a twinned layer disposed on at least one side of the TIM and in direct contact with the TIM.

Another aspect of the disclosure pertains to a method for forming a package structure. The method includes: disposing a chip on a substrate, wherein the chip has a backside surface away from the substrate; providing a heat sink, wherein the heat sink has a surface corresponding to the backside surface of the chip, and the chip has an orthogonal projection area on the surface of the heat sink; forming a twinned layer on the backside surface of the chip and/or the surface of the heat sink; disposing a thermal interface material (TIM) on the twinned layer; and bonding the surface of the heat sink toward the backside surface of the chip so that the twinned layer may be positioned on at least one side of the TIM.

### BRIEF DESCRIPTION OF THE DRAWINGS

Aspects of the present disclosure are better understood from the following detailed description when read with the accompanying figures. It is worth noting that some features may not be drawn to scale in accordance with the standard practice in the industry. In fact, the dimensions of the various features may be arbitrarily increased or reduced for clarity of discussion. It is also emphasized that the drawings appended illustrate only typical embodiments of this disclosure and are therefore not to be considered limiting in scope, for the disclosure may apply equally well to other embodiments.

FIGS. 1-4 are cross-sectional views of various stages of manufacturing a package structure, in accordance with some embodiments.

FIG. 5 is a cross-sectional view of a package structure, in accordance with some embodiments.

FIGS. 6-8 are cross-sectional views of various stages of manufacturing a package structure, in accordance with some other embodiments.

FIG. 9 is a cross-sectional view of a package structure, in accordance with some other embodiments.

FIGS. 10-15 are cross-sectional views of various stages of manufacturing a package structure, in accordance with some further embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present. When an element or layer is referred to as being “on” another element or layer, it is directly on and in contact with the other element or layer.

The terms used in the present specification are merely used to describe particular embodiments, and are not intended to limit the inventive concept. An expression used in the singular encompasses the expression of the plural, unless it has a clearly different meaning in the context. In the present specification, it is to be understood that the terms such as “including,” “having,” or “comprising,” etc. are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

The present disclosure provides a package structure with a twinned layer. The twinned layer located between the thermal interface material (TIM) and the chip and/or heat sink can reduce the formation of voids at the interface of the TIM close to the chip and/or heat sink during the hot press process. This, in turn, improves the chip-side coverage of the TIM on the backside surface of the chip and/or heat sink-side coverage of the TIM on the surface of the heat sink. This helps to improve the heat dissipation performance and reliability of the package structure. By applying pressure to the TIM before pressing the chip and heat sink together, the TIM is affixed on the twinned layer, achieving temporary positioning. This prevents the TIM from slipping out of place before the chip and heat sink are pressed together, thereby eliminating the need for the organic adhesive used in the existing techniques. Furthermore, the hot press process not only melts the TIM but also soft-bakes the adhesive, simplifying the process, and reducing both the production cost and the production time.

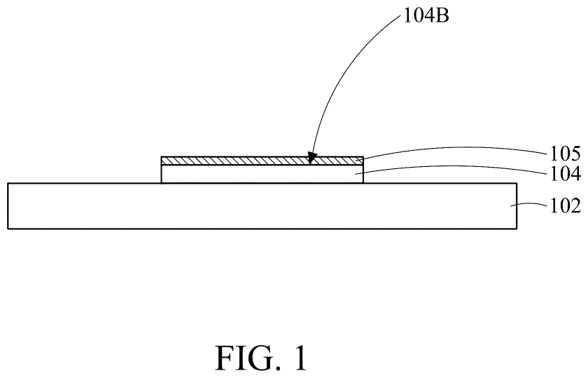

FIGS. 1-4 are cross-sectional views of various stages of manufacturing a package structure, in accordance with some embodiments.

Referring to FIG. 1, a chip 104 is disposed on a substrate 102. In some embodiments, the substrate 102 may include a printed circuit board (PCB), a wafer substrate, an integrated circuit (IC), an interposer, a chip carrier, a circuit carrier, and display device. In some embodiments, the chip 104 may include a semiconductor chip. The semiconductor chip may be, for example, a small piece of the semiconductor wafer formed by separating the semiconductor wafer into individual dies after performing semiconductor processes on the semiconductor wafer. The chip 104 may include an integrated circuit for processing and/or storing data, such as field programmable gate array (FPGA), processing unit (such as graphics processing unit (GPU)), central processing unit (CPU), application specific integrated circuit (ASIC), memory device (such as memory controller or memory), and so on. In some embodiments, the chip 104 may include a single crystal of a material of Si, Ge, SiC, sapphire, GaAs, and GaN. In some embodiments, attaching the chip 104 to the substrate 102 may include using a polymer adhesive, a solder, or a combination thereof to physically connect the chip 104 to the substrate 102.

In an embodiment, the chip 104 has a backside surface 104B away from the substrate 102 (the surface facing upward in FIG. 1). In an embodiment, the chip 104 optionally includes a metal layer 105 on the backside surface 104B. The metal layer 150 is configured to improve the heat dissipation performance of the package structure 100 and reduce the thermal impedance of the package structure 100, but the present disclosure is not limited thereto.

In some embodiments, the metal layer 105 may include at least one of Al/Ti/NiV/Au, Al/Cr/NiV/Au, Al/NiV/Au, Al/W/Au, Ti/NiV/Au, TiW/Au, Cr/NiV/Au, Cr/Au, W/Au, WTi/Au, WTi/Ti/Au, Al/Ti/Ni/Au, Ti/Ni/Ag, Ti/Ag, Al/Ti/NiV/Ag, Al/Cr/NiV/Ag, Al/NiV/Ag, Al/W/Ag, Ti/NiV/Ag, TiW/Ag, Cr/NiV/Ag, Cr/Ag, W/Ag, WTi/Ag, WTi/Ti/Ag, Al/Ti/Ni/Ag, Rh, Ir, Pd, and Pt. In some embodiments, the metal layer 105 may have a thickness ranging from 0.001 to 10 μm (such as 0.5 μm to 1.6 μm or 0.1 μm to 2 μm). In some embodiments, the method for forming the metal layer 105 may include sputtering, evaporation, electroplating, and any suitable deposition process.

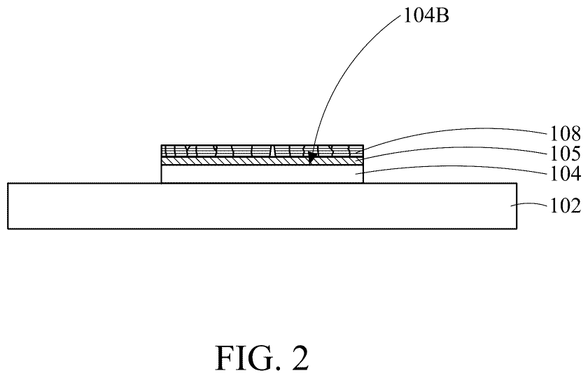

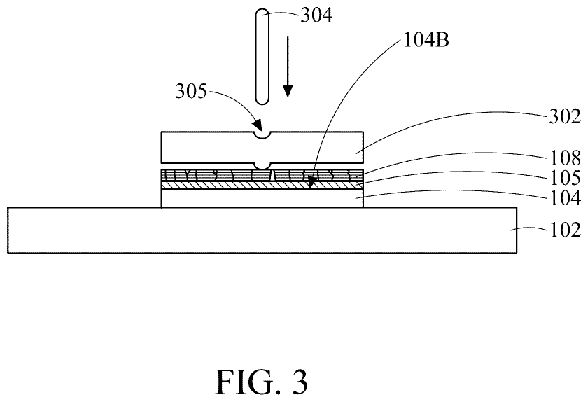

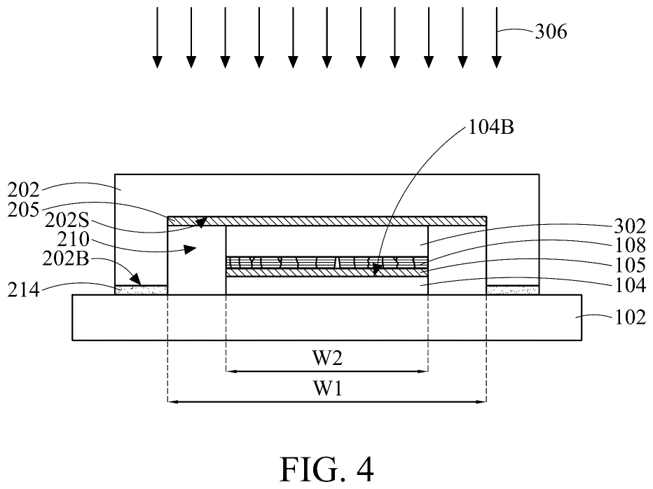

Referring to FIG. 2, a twinned layer 108 is formed on the chip 104 (or on the metal layer 105, if present). In some embodiments, the formation of twinned structures is driven by the accumulation of strain energy within the material, which causes atoms in certain regions to undergo uniform shear displacement to form lattice positions that are mirror-symmetrical with respect to the not sheared atoms within the grain. In general, the twinned may include an annealing twinned and a mechanical twinned. In addition to the properties of the metal itself, twinned structures exhibit characteristics such as improved oxidation resistance, corrosion resistance, electrical conductivity, thermal conductivity, and high-temperature stability. In some embodiments, the twinned layer 108 has at least 1% (e.g., at least 10%, at least 20%, at least 30%, at least 40%, at least 50%, at least 60%, at least 70%, at least 80%, or at least 90%) of twinned structures in its crystalline structure, which can exhibit a high diffusion rate. Therefore, it provides better bonding performance with the thermal interface material (TIM) 302 (shown in FIG. 3), which helps prevent the TIM 302 from slipping out of place. Moreover, during the hot press process 306 where the heat sink 202 and the chip 104 are pressed together, it is possible to reduce the formation of voids at the interface of the TIM 302 adjacent to the chip 104. This will be described in detail later in conjunction with FIG. 4. In some embodiments, the twinned structures may include various types (e.g., the annealing twinned or the mechanical twinned) and sizes (e.g., nano-twinned), and may include multiple twin boundaries, such as Σ3, Σ9, or Σ27.

In some embodiments, the twinned layer 108 may include gold, silver, copper, or silver-copper alloy. In some embodiments, the twinned layer 108 may have a thickness ranging from 0.1 to 100 μm (e.g., 0.5 to 10 μm). If the thickness of the twinned layer 108 is less than 0.1 μm, the advantages of the twinned structure (e.g., high diffusion rate) are not significant. Conversely, if the thickness of the twinned layer 108 is greater than 100 μm, the twinned layer 108 is prone to peeling off from the chip 104 (or from the metal layer 105, if present).

Referring to FIG. 3, a thermal interface material (TIM) 302 is disposed on the twinned layer 108. In some embodiments, the TIM 302 is configured to fill the contact gap between the chip 104 and a heat sink 302 (as illustrated in FIG. 4) during the press process, improve the overall heat dissipation performance of the package structure 100, and effectively reduce the thermal impedance of the package structure 100. For example, it facilitates the transfer of heat generated by the chip 104 to the heat sink 202. In some embodiments, the TIM 302 may include phase change materials, metal alloys, or any other suitable thermal interface materials.

In this embodiment, the TIM 302 may include an indium-based alloy or a tin-based alloy. In the present disclosure, the term “indium-based alloy” used herein includes an alloy containing at least indium. The alloy containing indium may be formed of (1) indium (In) and (2) at least one of bismuth (Bi), tin (Sn), and silver (Ag) such as indium-bismuth alloy, indium-bismuth-tin alloy, indium-tin alloy, or indium-silver alloy. In some embodiments, the indium-based alloy includes at least one of 30 to 35 wt % of Bi, 15 to 18 wt % of Sn and a balance of In, with a melting point of 55 to 65° C.; 30 to 35 wt % of Bi and a balance of In, with a melting point of 70 to 75° C.; 52 to 60 wt % of Bi, 15 to 18 wt % of Sn and a balance of In, with a melting point of 80 to 85° C.; 48 to 50 wt % of Sn and a balance of In, with a melting point of 110 to 120° C.; 0.1 to 15 wt % of Ag and a balance of In, with a melting point of 140 to 280° C.; and 100 wt % of indium, with a melting point of 150 to 160° C. In the present disclosure, the term “tin-based alloy” used herein includes an alloy containing at least tin. The alloy containing tin may be formed of (1) tin (Sn) and (2) at least one of copper (Cu), nickel (Ni), silver (Ag), or germanium (Ge). In some embodiments, the tin-based alloy includes at least one of tin, tin-silver, tin-silver-copper, or tin-silver-copper-nickel-germanium.

In some embodiments, in order to prevent the TIM 302 from slipping out of place before the heat sink 202 and the chip 104 are pressed together (as shown in FIG. 4), which could lead to incomplete coverage of the entire backside surface 104B of the chip 104 and reduce heat dissipation performance, an organic adhesive (not shown) may be applied before placing the TIM 302, thereby preventing the TIM 302 from slipping out of place. The organic adhesive may include fixing adhesive, flux, or any suitable adhesive material.

In other embodiments, pressure may be applied to the TIM 302 toward the surface of the twinned layer 108 (e.g., using a press head 304), as indicated by the downward arrows representing the direction of the applied pressure. This pressure ensures that the TIM 302 is fixed on the twinned layer 108, achieving temporary positioning. Specifically, the TIM 302 is first placed on the twinned layer 108, and then pressure is applied to the surface of the TIM 302 (e.g., using a press head 304) to form an indentation 305. It should be noted that although FIG. 3 shows pressure applied at a single point on the surface of the TIM 302 to create one indentation 305, but the present disclosure is not limited thereto. In other embodiments, pressure at multiple points may be applied at any position on the surface of the TIM 302 to form multiple indentation 305 according to practical requirements. That is, pressure may be applied to the TIM 302 toward the surface of the twinned layer 108 at one or more points (e.g., using the press head 304). In addition, although the press head 304 and the indentation 305 as illustrated in FIG. 3 have a circular profile, but the present disclosure is not limited thereto. In other embodiments, the press head 304 may have a profile of any shape, and the indentation 305 has a profile corresponding to that of the press head 304.

In some embodiments, at room temperature, a force greater than 1 gf/cm² may be applied to the surface of the TIM 302 for a duration longer than 0.1 seconds (e.g., 1 second), to temporarily fix the TIM 302 onto the twinned layer 108. As mentioned above, due to the high diffusion characteristics of the twinned layer 108, after pressure is applied (e.g., using a press head 304), the twinned layer 108 can affix to the TIM 302 through room-temperature diffusion, thereby preventing the TIM 302 from slipping out of place before the heat sink 202 and the chip 104 are pressed together (as shown in FIG. 4). It should be noted that the TIM 302 is temporarily fixed onto the twinned layer 108 by applying pressure to its surface (e.g., using a press head 304), thereby eliminating the need the organic adhesive used in the existing techniques (e.g., fixing adhesive or flux). In other words, the TIM 302 is in direct contact with the twinned layer 108.

Referring to FIG. 4, a heat sink 202 having a surface 202S corresponding to the backside surface 104B of the chip 104 is provided. In some embodiments, the heat sink 202 may be a heat-dissipating metal lid and/or a cooling fin, but the present disclosure is not limited thereto. In other embodiments, the heat sink 202 may also be a passive heat dissipating device such as a heat pipe, or an active cooling component such as a cooling fan or a liquid cooling system. Any type and shape of heat dissipating device may be selected according to practical requirements. In some embodiments, the material of the heat sink 202 may include metals and/or metal alloys, such as copper (Cu), aluminum (Al), cobalt (Co), nickel (Ni), nickel plated copper, or a combination thereof, or any suitable metal material. In other embodiments, the heat sink 202 may also be made from composite materials, such as alloys, silicon carbide (SiC), aluminum nitride (AlN), graphite, similar materials, or combinations thereof.

In the following disclosure, the heat-dissipating metal lid (as shown in drawings) will be exemplified as the heat sink 202 for illustration purpose. In this embodiment, the heat sink 202 having a recess 210 located on the side of the heat sink 202 adjacent to the chip 104 (the side facing downward in FIG. 4). The lateral width W1 of the recess 210 is greater than the lateral width W2 of the chip 104 to ensure that the chip 104 can be accommodated within the recess 210 when the heat sink 202 and the chip 104 are pressed together (as shown in FIG. 4).

In an embodiment, the heat sink 202 optionally includes a metal layer 205 located on the surface 202S. The metal layer 205 is configured to improve the heat dissipation performance of the package structure 100 and reduce the thermal impedance of the package structure 100, but the present disclosure is not limited thereto. In some embodiments, the metal layer 205 may include at least one of Au, Ag, Cu, Ni, Ti/Ag, Ti/Ni/Ag, Ti/Cu, Ti/Ni/Cu, Ni/Ag, Ni/Au, Ni/Cu, Rh, Ir, Pd, and Pt. In some embodiments, the metal layer 205 may have a thickness ranging from 0.001 μm to 10 μm (such as 0.5 to 1.6 μm or 0.1 to 2 μm). In some embodiments, the method for forming the metal layer 205 may include sputtering, evaporation, electroplating, or any suitable deposition process.

Still referring to FIG. 4, the surface 202S of the heat sink 202 is pressed toward the backside surface 104B of the chip 104, so that the twinned layer 108 may be located on the side of the TIM 302 adjacent to the chip 104, thereby forming the package structure 100 of the present disclosure. Specifically, an adhesive 214 is applied on the substrate 102, and then a bottom surface 202B of the heat sink 202 is bonded to the substrate 102 through the adhesive 214. Next, the TIM 302 is melted through a hot press process 306.

In some embodiments, the hot press process 306 may include: applying a force greater than 1 gf/cm² (such as 55 gf/cm², 900 gf/cm², or 3700 gf/cm²) on the heat sink 202 for a duration of 2 seconds to 10 minutes (such as 5 seconds, 10 seconds, 20 seconds, or 1 minute) at a temperature greater than 50° C. (such as 135° C., 145° C., 155° C., or 165° C.) in a process chamber under pressure or vacuum. Under the process parameters within the above-mentioned conditions, voids forming in the TIM 302 can be effectively expelled. This approach helps to improve the reliability and heat dissipation performance of the package structure 100.

During the hot press process 306, the twinned layer 108 provided by the present disclosure can reduce the formation of voids at the interface of the TIM 302 adjacent to the chip 104, thereby increasing the chip-side coverage of the TIM 302 on the backside surface 104B of the chip 104 (e.g., greater than 90%, greater than 95%, or greater than 99%). This approach helps to improve the reliability and heat dissipation performance of the package structure 100. In addition, the execution of the hot press process 306 not only melts the TIM 302 but also soft-bakes the adhesive 214 (that is, turning the adhesive 214 into a partially-cured adhesive 214′), simplifying the process, and reducing both the production cost and the production time. The term “chip-side coverage” used herein refers to the ratio of the covered area of the TIM 302 on the backside surface 104B of the chip 104 to the surface area of the backside surface 104B of the chip 104. Generally, a higher coverage indicates fewer voids generated in the TIM 302.

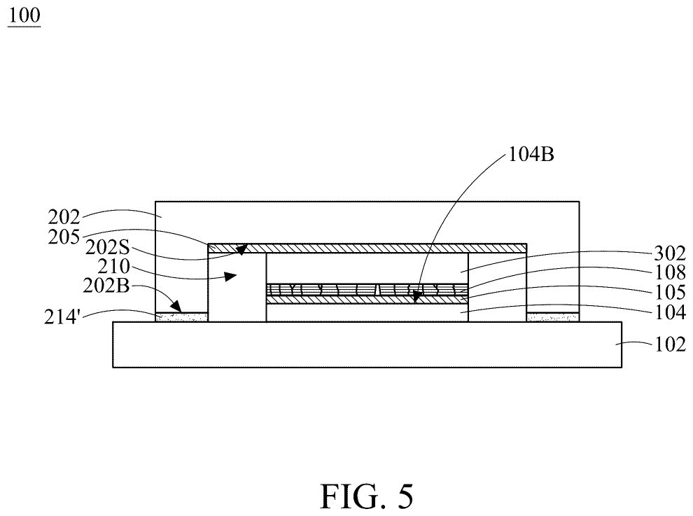

FIG. 5 is a cross-sectional view of a package structure 100, in accordance with some embodiments. The package structure 100 includes a substrate 102; a chip 104 disposed on the substrate 102 and having a backside surface 104B away from the substrate 102; a heat sink 202 disposed over the substrate 102, wherein the heat sink 202 has a surface 202S facing the chip 104; a thermal interface material (TIM) 302 disposed between the chip 104 and the heat sink 202; and a twinned layer 108 disposed on at least one side of the TIM 302 and in direct contact with the TIM 302. In this embodiment, the twinned layer 108 is located on the side of the TIM 302 adjacent to the chip 104. In other words, the twinned layer 108 is located between the TIM 302 and the chip 104.

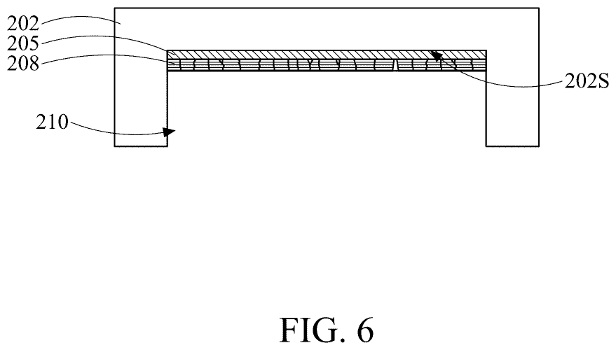

FIGS. 6-8 are cross-sectional views of various stages of manufacturing a package structure 200, in accordance with some other embodiments. It should be noted that some processes or devices are the same as, or similar to, those described in the embodiments above, and therefore the reference numerals and/or letters may be repeated. In this embodiment, there is a twinned layer 208 between the TIM 302 and the heat sink 202, while there is no twinned layer 108 between the chip 104 and the TIM 302.

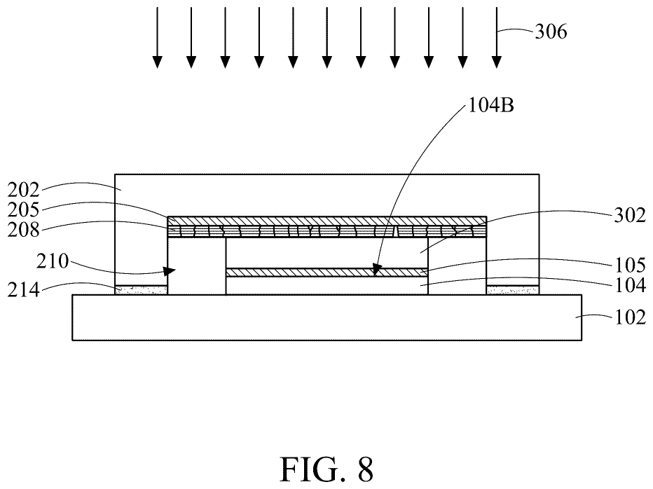

FIG. 6 follows the steps depicted in FIG. 1, a heat sink 202 having a surface 202S corresponding to the backside surface 104B of the chip 104 is provided, with a twinned layer 208 formed on the surface 202S of the heat sink 202 (or on the metal layer 205, if present). In some embodiments, the twinned layer 208 has at least 1% of twinned structures in its crystalline structure, which can exhibit a high diffusion rate. Therefore, it provides better bonding performance with a TIM 302 (shown in FIG. 8), which helps prevent the TIM 302 from slipping out of place. Moreover, during the hot press process 306 where the heat sink 202 and the chip 104 are pressed together, it is possible to reduce the formation of voids at the interface of the TIM 302 adjacent to the heat sink 202. This will be described in detail later in conjunction with FIG. 8.

In some embodiments, the material, thickness, and the formation method of the twinned layer 208 are similar to those of the twinned layer 108 described in FIG. 2, and their descriptions will not be repeated herein for brevity. In some embodiments, the twinned layer 208 fully covers the entire horizontal portion of the surface 202S of the heat sink 202 to ensure that the subsequently formed TIM 302 is in direct contact with the twinned layer 208 rather than the heat sink 202.

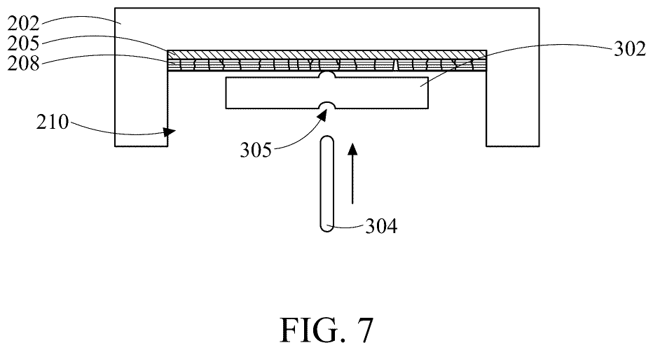

Referring to FIG. 7, in some embodiments, a thermal interface material (TIM) 302 is disposed on the twinned layer 208. In this embodiment, pressure may be applied to the TIM 302 toward the surface of the twinned layer 208 (e.g., using a press head 304), as indicated by the upward arrows representing the direction of the applied pressure. This pressure ensures that the TIM 302 is fixed on the twinned layer 108, achieving temporary positioning. Specifically, the TIM 302 is first placed on the twinned layer 208, and then pressure is applied to the surface of the TIM 302 (e.g., using the press head 304) to form an indentation 305.

In some embodiments, at room temperature, a force greater than 1 gf/cm² may be applied to the surface of the TIM 302 for a duration longer than 0.1 seconds (e.g., 1 second), to temporarily fix the TIM 302 onto the twinned layer 208. As mentioned above, due to the high diffusion characteristics of the twinned layer 208, after pressure is applied (e.g., using a press head 304), the twinned layer 208 can affix to the TIM 302 through room-temperature diffusion, thereby preventing the TIM 302 from slipping out of place before the heat sink 202 and the chip 104 are pressed together (as shown in FIG. 8). It should be noted that the TIM 302 is temporarily fixed onto the twinned layer 208 by applying pressure to its surface (e.g., using a press head 304), thereby eliminating the need the organic adhesive used in the existing techniques (e.g., fixing adhesive or flux). In other words, the TIM 302 is in direct contact with the twinned layer 208.

Referring to FIG. 8, the surface 202S of the heat sink 202 is pressed toward the backside surface 104B of the chip 104, so that the twinned layer 208 may be located on the side of the TIM 302, thereby forming the package structure 200 of the present disclosure. Specifically, an adhesive 214 is applied on the substrate 102, and then a bottom surface 202B of the heat sink 202 is bonded to the substrate 102 through the adhesive 214. Then, the TIM 302 is melted through a hot press process 306.

During the hot press process 306, the twinned layer 208 provided by the present disclosure can reduce the formation of voids at the interface of the TIM 302 adjacent to the heat sink 202, thereby increasing the heat sink-side coverage of the TIM 302 on the surface 202S of heat sink 202 (e.g., greater than 90%, greater than 95%, or greater than 99%). This approach helps to improve the reliability and heat dissipation performance of the package structure 200. In the present disclosure, the chip 104 has an orthogonal projection area on the surface 202S of the heat sink 202. The term “heat sink-side coverage” refers to the ratio of the covered area of the TIM 302 on the orthogonal projection area by an ultrasonic wave or X-ray to the orthogonal projection area. Generally, a higher coverage indicates fewer voids generated in the TIM 302.

It should be understood that after performing the hot press process 306, subsequent processes can be carried out as necessary to complete the production of the package structure. Since these processes are not directly related to the focus of this disclosure, they will not be described herein for brevity.

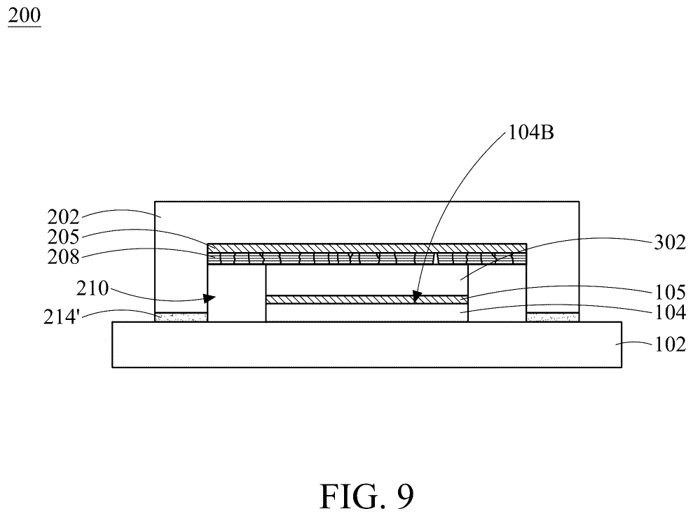

FIG. 9 is a cross-sectional view of a package structure 200, in accordance with some other embodiments. The package structure 200 as shown in FIG. 9 is similar to the package structure 100 as shown in FIG. 5, except that the twinned layer 208 is located on the side of the TIM 302 adjacent to the heat sink 202. In other words, the twinned layer 208 is located between the TIM 302 and the heat sink 202, while there is no twinned layer 108 between the chip 104 and the TIM 302.

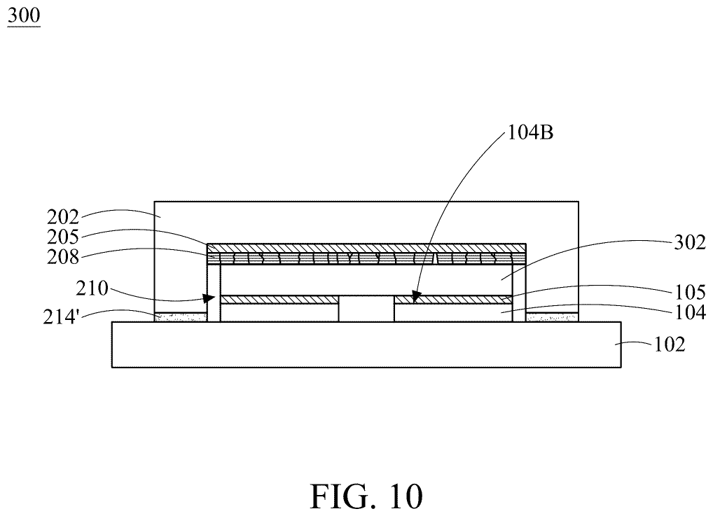

FIGS. 10-15 are cross-sectional views of various stages of manufacturing a package structure 300, 400, 500, 600, 700, and 800, in accordance with some further embodiments.

In some embodiments, the package structure 300 as shown in FIG. 10 is similar to the package structure 200 as shown in FIG. 9, except that the number of the chip 104 disposed on the substrate 102 is plural, and the single TIM 302 covers all the chips 104. By covering all the chips 104 with the single TIM 302, the process is simplified. It should be noted that although only two chips 104 are illustrated in FIG. 10, but the present disclosure is not limited thereto. In other embodiments, various numbers of the chips 104 may be disposed on the substrate 102 according to practical requirements such as three, four, and more chips 104.

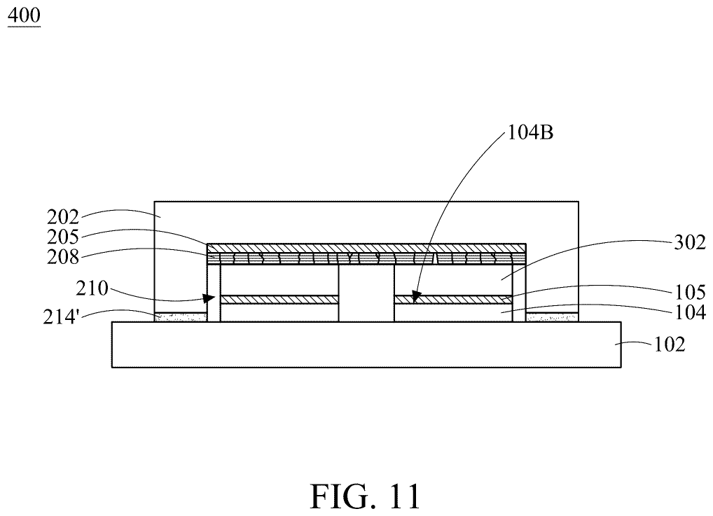

In some embodiments, the package structure 400 as shown in FIG. 11 is similar to the package structure 300 as shown in FIG. 10, except that each chip 104 is covered by a respective segment of the TIM 302, rather than using a single TIM 302 to cover all the chips 104. By using multiple segments of the TIM 302, it becomes possible to tailor the TIM 302 to the specific needs of each chip 104, such as variations in material properties or operating temperatures.

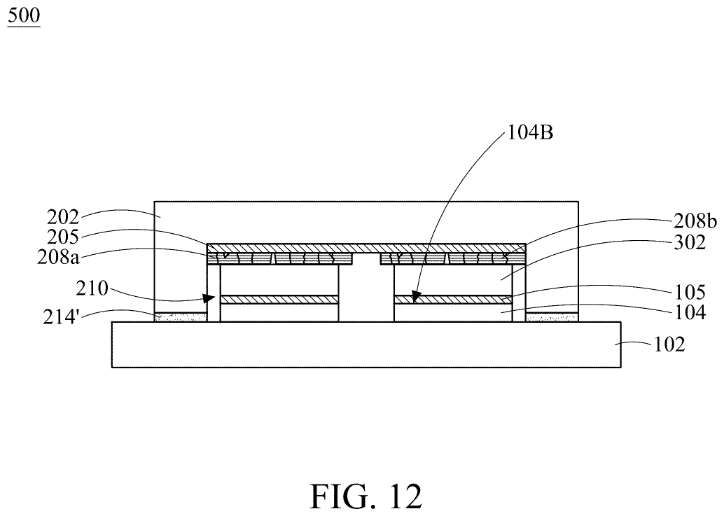

In some embodiments, the package structure 500 as shown in FIG. 12 is similar to the package structure 400 as shown in FIG. 11, except that the twinned layer 208 includes a plurality of discrete segments (e.g., the twinned layers 208a and 208b) each corresponding to a respective chip 104. As shown in FIG. 12, the twinned layers 208a and 208b are spaced apart from each other on the same level and are located on the metal layer 205. Since the twinned structure of the twinned layer 208 has better thermal reactivity with the TIM 302 compared to base metals (e.g., coarse-grained metals), using the plurality of discrete segments such as twinned layers 208a and 208b can limit the reactivity between the TIM 302 and the base metals.

In some embodiments, the metal layer 205 of the package structure 500 in FIG. 12 may include a plurality of discrete segments (not shown) spaced apart from each other on the same level, each corresponding to a plurality of discrete segments of the twinned layer 208 (e.g., the twinned layers 208a and 208b). Based on this arrangement, the amount of the metal layer 205 may be saved, and thus the production cost is reduced, but the disclosure is not limited thereto. In other embodiments, the metal layer 205 may include a plurality of discrete segments (not shown) collectively corresponding to a single twinned layer 208, thereby simplifying the process (i.e., reducing process complexity).

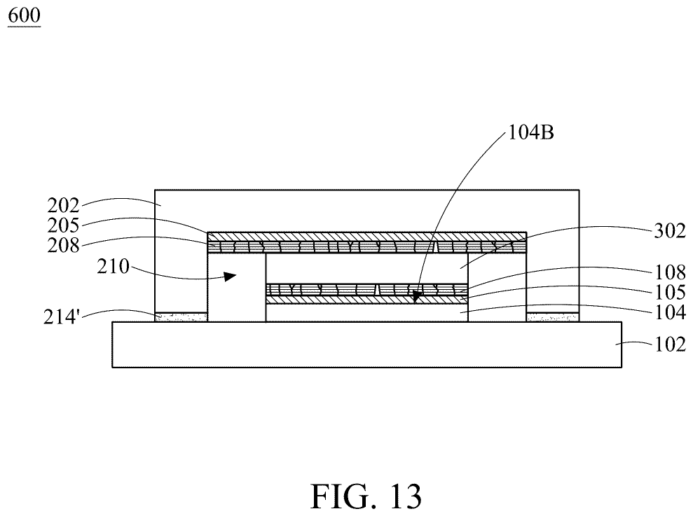

In some embodiments, the package structure 600 as shown in FIG. 13 is similar to the combination of the package structure 100 as shown in FIG. 9 and the package structure 200 as shown in FIG. 9. Specifically, the package structure 600 includes not only a twinned layer 108 located between the chip 104 and the TIM 302 but also a twinned layer 208 located between the heat sink 202 and the TIM 302. Compared to disposing a twinned layer 108 only on one side of the TIM 302, simultaneously disposing twinned layers 108 and 208 on both sides of the TIM 302 can reduce the formation of voids at both the interface of the TIM 302 adjacent to the chip 104 and the interface adjacent to the heat sink 202. This, in turn, further enhances the heat dissipation performance and reliability of the package structure 600.

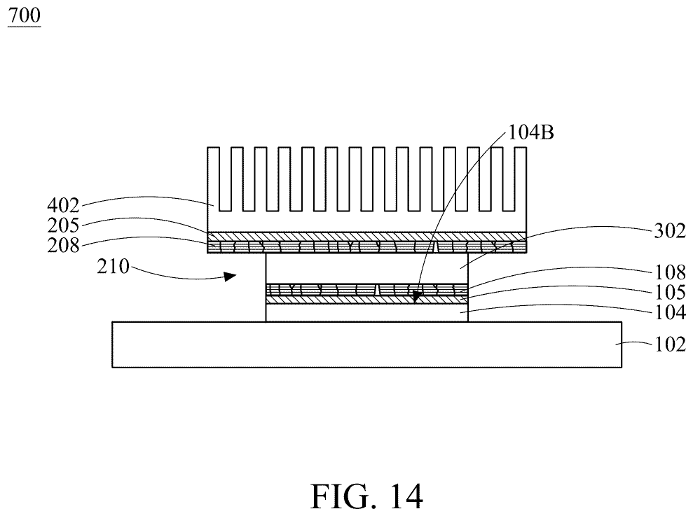

In some embodiments, the package structure 700 as shown in FIG. 14 is similar to the package structure 600 as shown in FIG. 13, except that the heat sink 402 is the cooling fin. Since the cooling fin has a larger heat dissipation area compared with the heat-dissipating metal lid, and thus it may conduct the heat generated during the operation of the chip 104 more quickly to achieve better heat dissipation performance.

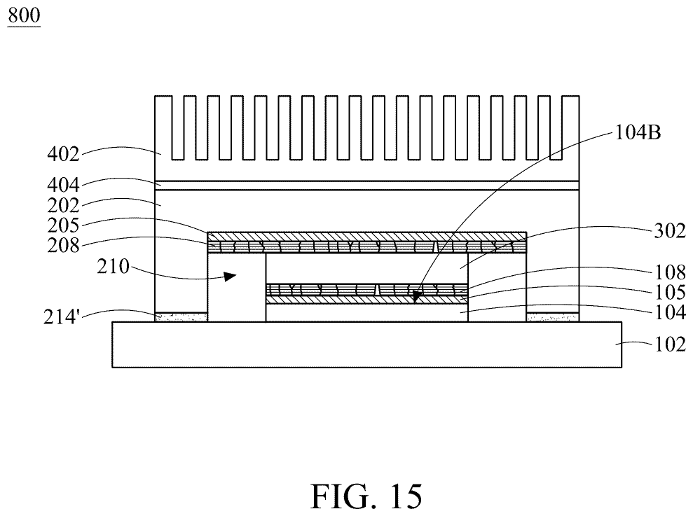

In some embodiments, the package structure 800 as shown in FIG. 15 is similar to the package structure 600 as shown in FIG. 13, except that the heat sink 202 bonded to the substrate 102 is the heat-dissipating metal lid, and after the heat sink 202 is bonded to the chip 104, another heat sink 402 is disposed on the heat-dissipating metal lid, in which the heat sink 402 is the cooling fin. Therefore, the heat dissipation area of the package structure 800 is further increased by the cooling fin. Specifically, after the heat sink 202 is bonded to the chip 104, a thermal interface material (TIM) 404 is disposed on a surface of the heat sink 202 away from the chip 104, and then the heat sink 402 is disposed on the thermal interface material 404. Therefore, the TIM 404 is affixed to the surface of heat sink 202 away from the chip 104. The method for applying TIM 404 to the heat sink 202 is similar to those of applying TIM 302 described in FIG. 3, and their descriptions will not be repeated herein for brevity. Subsequently, after disposing the heat sink 402 on the TIM 404, the hot press process 306 (as shown in FIG. 4) can be used to melt the TIM 404, filling the contact gaps between the heat sinks 202 and 402. As a result, the heat generated by the chip 104 can be transferred to the heat sink 202 through the TIM 302, and then further transferred to the heat sink 402 through the TIM 404.

In some embodiments, at a bonding site between the TIM 302 and the metal layer 105, the TIM 302 reacts with the metal layer 105 due to the heat generated during the operation of the chip 104, causing the metal layer 105 to at least partially fuse into the TIM 302. Specifically, the outermost metal layer of the metal layer 105 (such as gold (Au), silver (Ag), rhodium (Rh), iridium (Ir), palladium (Pd), or platinum (Pt)) may be completely or partially fused into the TIM 302, depending on the thickness of the outermost metal layer 105. For example, when the thickness of the outermost metal is less than 0.1 μm, the outermost metal in metal layer 105 may completely fuse into the TIM 302.

In some embodiments, at a bonding site between the TIM 302 and the metal layer 205, the TIM 302 reacts with the metal layer 205 due to the heat generated during the operation of the chip 104, causing the metal layer 205 to at least partially fuse into the TIM 302. Specifically, the outermost metal layer of the metal layer 205 (such as gold (Au), silver (Ag), rhodium (Rh), iridium (Ir), palladium (Pd), or platinum (Pt)) may be completely or partially fused into the TIM 302, depending on the thickness of the outermost metal layer 205. For example, when the thickness of the outermost metal is less than 0.1 μm, the outermost metal in metal layer 205 may completely fuse into the TIM 302.

In some embodiments, at a bonding site between the TIM 302 and the twinned layer 108, 208, the TIM 302 reacts with the twinned layer 108, 208 due to the heat generated during the operation of the chip 104, causing the twinned layer 108, 208 to at least partially fuse into the TIM 302. Specifically, the twinned layer 108, 208 may be completely or partially fused into the TIM 302, depending on the thickness of the twinned layer 108, 208. For example, when the thickness of the twinned layer 108, 208 is less than 0.1 μm, gold (Au), silver (Ag), or copper (Cu) in the twinned layer 108, 208 may completely fuse into the TIM 302.

It should be noted that the timing of the fusion of the metal layers 105 and 205, the twinned layer 108, or the twinned layer 208 into the TIM 302 is not limited to when the chip 104 is in operation. For example, during the hot press process 306, parts of the metal layers 105 and 205, the twinned layer 108, or the twinned layer 208 may fuse into the TIM 302. This fusion will continue to occur when the chip 104 is operating after the packaging is completed, but the present disclosure is not limited thereto. Any thermal process during the packaging could potentially cause such fusion to occur.

Several examples and comparative examples are provided below to specifically describe the effects that can be achieved by bonding the metal layer and the thermal interface material in the embodiment of the present disclosure.

### Comparative Examples 1-2: Directly Disposing the Thermal Interface Material Onto the Metal Layer

The chip 104 having the metal layer 105 (made of a material of Al/Ti/NiV/Au) was provided, and the TIM 302 (made of a material of 100 wt % indium) was directly disposed on the metal layer 105 (i.e., there was no twinned layer 108 between the chip 104 and the TIM 302). Then, pressure was applied using the press head 304 (applying a force of 0.1 gf/mm²) at two points on the surface of the TIM 302 to affix the TIM 302 on the chip 104, achieving temporary positioning. Afterward, the heat sink 202 and the chip 104 were pressed together, and the hot press process 306 was carried out under different conditions, as detailed in Table 1.

TABLE 1

| | Temperature | Force | Time |
|---|---|---|---|
| | (° C.) | (gf/cm²) | (s) |
| Comparative Example 1 | 165 | 55 | 5 |
| Comparative Example 2 | 155 | 55 | 20 |

### Examples 1-4: Disposing the Thermal Interface Material Onto the Twinned Layer

The chip 104 having the metal layer 105 (made of a material of Al/Ti) and the twinned layer 108 (made of a material of Ag having twinned structure) was provided, and the TIM 302 (made of a material of 100 wt % indium) was disposed on the twinned layer 108. Then, pressure was applied using the press head 304 (applying a force of 0.1 gf/mm²) at two points on the surface of the TIM 302 to affix the TIM 302 on the chip 104, achieving temporary positioning. Afterward, the heat sink 202 and the chip 104 were pressed together, and the hot press process 306 was carried out under different conditions, as detailed in Table 2.

TABLE 2

| | Temperature | Force | Time |
|---|---|---|---|
| | (° C.) | (gf/cm²) | (s) |
| Example 1 | 165 | 55 | 5 |
| Example 2 | 155 | 55 | 10 |
| Example 3 | 145 | 900 | 60 |
| Example 4 | 145 | 3700 | 60 |

### [Chip-Side Coverage Test]

After the hot press process 306, the TIM 302 over the chip 104 was scraped off using a spatula from the structures of Comparative Examples 1-2 and Examples 1-4. The coverage of the TIM 302 on the chip 104 was measured using the LM-X, a full-range automatic image dimension measurement instrument manufactured by Keyence Corporation. The results are shown in Table 3.

TABLE 3

| | Coverage |
|---|---|
| Comparative Example 1 | >40% |
| Comparative Example 2 | 0% |
| Example 1 | >99% |
| Example 2 | >99% |
| Example 3 | >95% |
| Example 4 | >95% |

According to the results as shown in Table 3, under the same process conditions of the hot pressing process 306, the coverage of disposing the TIM 302 on the twinned layer 108 (Example 1) is improved compared to directly disposing the TIM 302 on the metal layer 105 (Comparative Example 1).

In summary, some embodiments of the present disclosure offer several benefits. The present disclosure provides the twinned layer located between the thermal interface material (TIM) and the chip and/or heat sink can reduce the formation of voids at the interface of the TIM close to the chip and/or heat sink during the hot press process. This, in turn, improves the chip-side coverage of the TIM on the backside surface of the chip and/or heat sink-side coverage of the TIM on the surface of the heat sink. This helps to improve the heat dissipation performance and reliability of the package structure. In addition, by applying pressure to the TIM before the chip and heat sink are pressed together, the TIM is affixed on the twinned layer, achieving temporary positioning. This prevents the TIM from slipping out of place before the chip and heat sink are pressed together, thereby eliminating the need for the organic adhesive used in the existing techniques. Furthermore, the hot press process not only melts the TIM but also soft-bakes the adhesive, simplifying the process, and reducing both the production cost and the production time.

While the present disclosure has been described by way of example and in terms of the preferred embodiments, it should be understood that the present disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A package structure, comprising:
a substrate;
a chip disposed on the substrate and having a backside surface away from the substrate;
a heat sink disposed over the substrate, wherein the heat sink has a surface facing the chip;
a thermal interface material (TIM) disposed between the chip and the heat sink; and
a twinned layer disposed on at least one side of the TIM and in direct contact with the TIM.

2. The package structure of claim 1, wherein the twinned layer is disposed between the TIM and the heat sink, and the twinned layer comprises a plurality of discrete segments spaced apart from each other on a same level.

3. The package structure of claim 1, wherein the twinned layer comprises gold, silver, copper, or silver-copper alloy, and has at least 1% twinned structures in its crystal structure.

4. The package structure of claim 1, wherein the twinned layer has a thickness of 0.1 to 100 μm.

5. The package structure of claim 1, wherein the chip comprises a metal layer on the backside surface, wherein the metal layer comprises at least one of Al/Ti/NiV/Au, Al/Cr/NiV/Au, Al/NiV/Au, Al/W/Au, Ti/NiV/Au, TiW/Au, Cr/NiV/Au, Cr/Au, W/Au, WTi/Au, WTi/Ti/Au, Al/Ti/Ni/Au, Ti/Ni/Ag, Ti/Ag, Al/Ti/NiV/Ag, Al/Cr/NiV/Ag, Al/NiV/Ag, Al/W/Ag, Ti/NiV/Ag, TiW/Ag, Cr/NiV/Ag, Cr/Ag, W/Ag, WTi/Ag, WTi/Ti/Ag, Al/Ti/Ni/Ag, Rh, Ir, Pd, and Pt, and the metal layer has a thickness of 0.001 to 10 μm.

6. The package structure of claim 1, wherein the heat sink is a heat-dissipating metal lid and/or a cooling fin.

7. The package structure of claim 1, wherein the heat sink comprises copper (Cu), aluminum (Al), cobalt (Co), nickel (Ni), nickel plated copper, silicon carbide (SiC), nitrogen aluminum (AIN), graphite, or a combination thereof.

8. The package structure of claim 1, wherein the heat sink comprises a metal layer on the surface, wherein the metal layer comprises at least one of Au, Ag, Cu, Ni, Ti/Ag, Ti/Ni/Ag, Ti/Cu, Ti/Ni/Cu, Ni/Ag, Ni/Au, Ni/Cu, Rh, Ir, Pd, and Pt, and the metal layer has a thickness of 0.001 to 10 μm.

9. The package structure of claim 8, wherein the metal layer comprises a plurality of discrete portions spaced apart from each other on a same level.

10. The package structure of claim 1, wherein the TIM comprises an indium-based alloy or a tin-based alloy.

11. The package structure of claim 10, wherein the indium-based alloy comprises at least one of:
30 to 35 wt % of bismuth, 15 to 18 wt % of tin, and a balance of indium, with a melting point of 55 to 65° C.;
30 to 35 wt % of bismuth and a balance of indium, with a melting point of 70 to 75° C.;
52 to 60 wt % of bismuth, 15 to 18 wt % of tin, and a balance of indium, with a melting point of 80 to 85° C.;
48 to 50 wt % of tin and a balance of indium, with a melting point of 110 to 120° C.;
0.1 to 15 wt % of silver and a balance of indium, with a melting point of 140 to 280° C.; and
100 wt % of indium with a melting point of 150 to 160° C.

12. The package structure of claim 10, wherein the tin-based alloy comprises tin, tin-silver, tin-silver-copper, or tin-silver-copper-nickel-germanium.

13. The package structure of claim 1, wherein the chip has an orthogonal projection area on the surface of the heat sink, and a coverage of the TIM on the backside surface of the chip or the orthogonal projection area is greater than 90%.

14. The package structure of claim 1, wherein the twinned layer is configured to at least partially fuse into the TIM.

15. A method for forming a package structure, comprising:
disposing a chip on a substrate, wherein the chip has a backside surface away from the substrate;
providing a heat sink, wherein the heat sink has a surface corresponding to the backside surface of the chip, and the chip has an orthogonal projection area on the surface of the heat sink;
forming a twinned layer on the backside surface of the chip and/or the surface of the heat sink;
disposing a thermal interface material (TIM) on the twinned layer; and
bonding the surface of the heat sink toward the backside surface of the chip so that the twinned layer is positioned on at least one side of the TIM.

16. The method of claim 15, wherein disposing the TIM on the twinned layer comprises applying pressure at a single point or multiple points to the TIM towards the surface of the twinned layer to affix the TIM on the twinned layer.

17. The method of claim 15, wherein bonding the surface of the heat sink toward the backside surface of the chip comprises:
performing a hot press process to make a coverage of the TIM melted on the backside surface of the chip or the orthogonal projection area greater than 90%.

18. The method of claim 17, wherein the hot press process comprises applying a force greater than 1 gf/cm² to the heat sink for a duration of 2 seconds to 10 minutes at a temperature greater than 50° C. in a process chamber under pressure or vacuum.

19. The method of claim 15, wherein the heat sink is a heat-dissipating metal lid, and after bonding the heat sink to the chip, the method further comprises disposing a cooling fin over the heat-dissipating metal lid.

20. The method of claim 15, wherein, prior to forming the twinned layer, the method further comprises forming a metal layer on the backside surface of the chip and/or the surface of the heat sink.

21. The method of claim 20, wherein the metal layer and/or the twinned layer is at least partially fused into the TIM.
